(19) United States
(12) Patent Application Publication
(10) Pub. No.: US 2019/0378780 A1
(43) Pub. Date: Dec. 12, 2019

(54) HEAT-DISSIPATING ARRANGEMENT AND METHOD FOR THE PRODUCTION THEREOF

(71) Applicant: ZF Friedrichshafen AG, Friedrichshafen (DE)

(72) Inventors: Mathias Hauslmann, Amberg (DE); Markus Bauernfeind, Pegnitz (DE); Hermann Josef Robin, Regensburg (DE); Kurt Michel, Pegnitz (DE)

(73) Assignee: ZF Friedrichshafen AG, Friedrichshafen (DE)

(21) Appl. No.: 16/341,571

(22) PCT Filed: Sep. 19, 2017
(86) PCT No.: PCT/EP2017/073646

§ 371 Date: Apr. 12, 2019

(30) Foreign Application Priority Data
Oct. 17, 2016 (DE) 10 2016 220 265.0

(51) Int. Cl. H01L 23/427; F28D 15/02; H05K 7/20

(52) U.S. Cl. CPC H01L 23/427; F28D 15/0233; B33Y 80/00; H05K 7/20936; H05K 7/20336

(57) ABSTRACT

A heat dissipating assembly is created, wherein the heat dissipating assembly comprises at least one power module that contains a printed circuit board (2) populated with components (3) that need to be cooled, and at least one heat sink (1) located on the printed circuit board (2) and over the components (3) that are to be cooled, wherein there is at least one thermally conductive element (100) located on at least one of the components (3) that is to be cooled, which has a predefined structure, which extends away from the printed circuit board (2) into the heat sink (1), and wherein the thermally conductive element (100) contains a heat dissipating medium in its interior.

The present invention relates to a heat dissipating assembly according to the preamble of claim 1 and a method for the production thereof according to the preamble of claim 7.

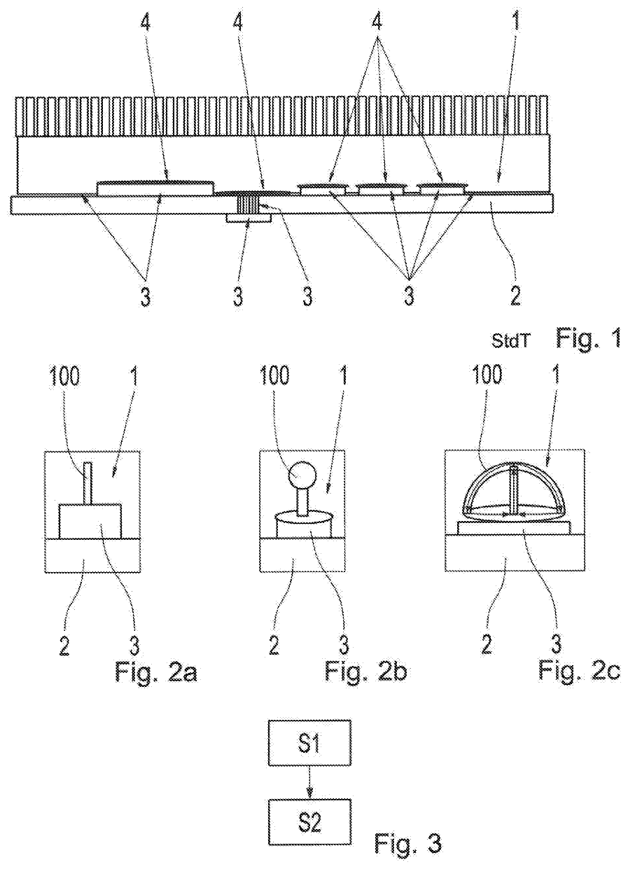

Heat dissipation elements such as heat sinks in power electronics and in control devices are used for cooling different components, e.g. components or structures on a printed circuit board. Because of tolerances and existing surface conditions, a direct contact of the heat sink with the components is not optimal for thermal conductance. For this reason, it has been necessary with known cooling strategies to insert a gap-bridging and thermally conductive layer to improve the thermal connection, as is shown in FIG. 1 and provided with the reference symbol 4. Such a gap-bridging and thermally conductive layer 4 can be a thermally conductive paste or a so-called gap filler, placed on the appropriate components 3, e.g. components, structures or paths on the printed circuit board 2. Both a thermally conductive paste and a gap filler require a certain thickness, wherein the thermal conductance of such media is normally lower than that of metal, such that the cooling effect via the heat sink 1 is affected, and the maximum loss conductance is reduced.

Other disadvantages of known heat dissipating assemblies also include the fact that a separate processing step is necessary in the production thereof, for producing the thermally conductive layer 4. Furthermore, the heat sink requires a larger cross section for the necessary heat dissipation, to prevent heat build-up. This can lead to problems regarding space when installing the assembly.

For this reason, the object of the invention is to create a heat dissipating assembly and a method for the production of this assembly, by means of which the aforementioned disadvantages are overcome.

This object is achieved according to the invention by the features of the independent claims. Advantageous designs are the subject matter of the dependent claims.

A heat dissipating assembly is provided, wherein the heat dissipating assembly has at least one power module, which has a printed circuit board populated with components that need to be cooled, and at least one heat sink located on the printed circuit board and above the components that are to be cooled, wherein at least one thermally conductive element is located on at least one of the components that is to be cooled, which has a predefined structure, which extends away from the printed circuit board into the heat sink, and wherein the thermally conductive element has a heat dissipating medium in its interior.

A power module is also an assembly containing a printed circuit board with at least one electrical power element located thereon, e.g. a semiconductor element.

In one embodiment, the thermally conductive element is in the form of a heatpipe cooler. In one embodiment, the thermally conductive element has a hollow structure, into which the heat dissipating medium is introduced, or a hollow structure in which the heat dissipating medium circulates.

In one embodiment, the thermally conductive element is a separate component on the at least one component that needs to be cooled, or is integrated in the heat sink by means of a printing process.

In one embodiment, the thermally conductive element has at least one hole facing the at least one of the components that is to be cooled, through which the heat dissipating medium can exit and come in contact with the component such that a gap existing between the component and the thermally conductive element is at least partially filled.

In one embodiment, the heat dissipating medium is a liquid, gas, sodium, or some other material suitable for heat dissipation.

A method for producing a heat dissipating assembly is proposed according to the invention, wherein the heat dissipating assembly has at least one power module, which has a printed circuit board populated with components that need to be cooled, and at least one heat sink located on the printed circuit board, above the components that are to be cooled, wherein in a first step, at least one first thermally conductive element is placed on the printed circuit board on at least one of the components, which has a predefined structure, which extends away from the printed circuit board, and in a second step, the heat sink is placed above the components on the printed circuit board and the at least one thermally conductive element located thereon, wherein the thermally conductive element contains a heat dissipating medium in its interior, or a heat dissipating medium is introduced therein in or prior to the first step, or in or after the second step, and/or in an alternative first step, or in the second step, the heat sink is placed above the components of the printed circuit board, wherein at least one second thermally conductive element is integrated in the heat sink in the production of the heat sink, and in a second step, a heat dissipating medium is introduced into the second and/or first thermally conductive element.

In one embodiment, the at least one first or second thermally conductive element has a hole through which the heat dissipating medium is introduced into the thermally conductive element, wherein the hole opens toward the components in order to allow the heat dissipating medium to at least partially fill a gap located between the components and the thermally conductive element.

In one embodiment, the at least one first or second thermally conductive element has a hole through which the heat dissipating medium is introduced into the thermally conductive element, wherein the hole is sealed after it has been filled with the heat dissipating medium.

In one embodiment, the predefined structure of each thermally conductive element is such that the heat dissipating medium circulates therein.

By providing separate thermally conductive elements of different structures and designs extending into the heat sink, the heat dissipation capacity, or heat distribution is improved in the overall assembly. Because the structures of the thermally conductive elements can be produced individually, a heat dissipation and distribution coordinated to the respective components can take place in the heat sink. An improved heat dissipation or distribution into the heat sink can be ensured through the heat dissipating medium in the thermally conductive elements. Furthermore, with an open structure of the thermally conductive element, small gaps between components and the thermally conductive element can be bridged in that the heat dissipating medium enters the gap, by means of which the heat dissipation is further improved.

The method for producing the assembly is simplified and inexpensive due to the components that can be produced separately and the possibility of using 3D printing for the production thereof, or a combination thereof. Furthermore, a separate thermally conductive element can be produced for each component, and tailored thereto, such that the best possible heat dissipation can be ensured for each component.

Further features and advantages of the invention can be derived from the following description of exemplary embodiments of the invention, based on the figures in the drawings, which show details of the invention, and from the claims. The individual features can be realized in and of themselves or in numerous arbitrary combinations in variations of the invention.

Preferred embodiments of the invention shall be explained below in greater detail, in reference to the attached drawings. Therein:

FIG. 1 shows an illustration of a heat dissipating assembly according to the prior art;

FIGS. 2a to 2c each show illustrations of different embodiments of a heat dissipating assembly according to the present invention;

FIG. 3 shows a flow chart of the method according to one embodiment of the present invention.

In the following description of the figures, identical elements and functions are provided with the same reference symbols.

An intermediate layer is not necessary for a better thermal connection or heat dissipation between the heat sink and the components populating the printed circuit board due to the method according to the invention. In order to connect the heat sink such that it conducts heat better, thermally conductive elements can be integrated directly in the heat sink, or can be integrated as separate components in the production thereof. The thermally conductive elements have a special structure, and are preferably at least partially filled with a thermally conductive medium, hereinafter referred to simply as a medium. The medium can be present in the closed thermally conductive element with or without circulation, or it can be in contact with the corresponding components, i.e. the thermally conductive element has a structure that opens toward the component(s) on which it is located. The thermally conductive element can also be procured or produced as a separate component, which is then applied to one or more components, and integrated in the assembly. The integration can take place, e.g., by reprinting the printed circuit board and the components thereon with thermally conductive elements of the heat sink located thereon by means of 3D printing.

Heat dissipating elements according to different possible embodiments of the present invention are shown in FIGS. 2a to 2c.

Each of the embodiments shown in the figures shall be explained separately below. Depending on the application, a combination of different heat dissipating elements shown in the embodiments can be used. The description relates to the components that are to be cooled. The printed circuit board can also have other components that do not need to be cooled.

FIG. 2a shows a thermally conductive element 100 in the form of a heatpipe and located on a component 3 of the printed circuit board 2. The heatpipe 100 is located on the component 3 from which the heat is to be dissipated as a component that has been produced or procured separately. The heatpipe structure is thus not in direct contact with the component 3. This simplifies the structure of the overall assembly, because with a direct contact to the component 3, the complex structure of the heatpipe 100 must be formed on the component, e.g. by means of a printing process. By forming the heatpipe 100 directly in the heat sink 1, although the complex structure of the heatpipe 100 must be obtained, there is a better thermal connection than with a component produced separately, which is embedded in the heat sink 1, i.e. encompassed by the heat sink, preferably printed therein. In this regard, with certain embodiments the heatpipe can also be formed on the components or in the heat sink. Heatpipes are known from the prior art, and need no further explanation here. As a rule, they have a closed, tube-like structure with complex internal branchings or capillaries, through which a medium, which vaporizes when subjected to heat, circulates, in order to discharge heat.

FIG. 2b shows a thermally conductive element 100 in the form of a tower, with a medium therein for heat dissipation. In this case, the medium is stationary, thus not circulating. FIG. 2c shows a dome in the form of a tube, with a thermally conductive element 100 in the form of a central tube, in which the medium circulates due to the structure thereof. In this case, the medium circulates from the printed circuit board 2 via the central tube, and is then distributed toward the left and right, in order to flow back to the base via the tube-shaped dome, and back to the middle where it continues to circulate.

The embodiments of the thermally conductive element 100 shown in FIGS. 2b and 2c, and the variations thereof, can be printed directly on the components 3, e.g. in the same step as the heat sink 1. The thermally conductive element 100 can also be produced or procured as a separate component. There is a heat dissipating medium in the thermally conductive element 100, e.g. a liquid or a gas or a special metal such as sodium. This medium can already be in the separate component, or it can be introduced into the component subsequently. When the thermally conductive element 100 is produced with the heat sink 1, e.g. by means of a printing process, e.g. a 3D printing process, the medium can be introduced into the thermally conductive element 100 after producing the heat sink 1.

In order to introduce the medium, there can be a hole, preferably located on the side of the thermally conductive element 100 facing the component 3 that is to be cooled. This hole can remain open, depending on the application, after the medium is introduced, or it can be sealed, e.g. with a thin coating that can be printed, glued, or attached thereon with other means. When the hole is not closed, the medium can exit the hole, and at least partially fill a gap that may exist due to the production method between the component 3 and the thermally conductive element 100. As a result, this gap can be bridged, and the heat dissipation is further improved.

The structures of the thermally conductive element 4 shown in FIGS. 2b and 2c differ, depending on the component that is to be cooled. The precise structure of the thermally conductive element 100 that is to be used can be determined by the person skilled in the art according to his experience from tests, or from a calculation or simulation, and depends on the components that are to be cooled and the available production methods, as described above.

The embodiment illustrated in FIG. 2b can be formed by a hollow element. This can expand upward, thus away from the printed circuit board 2 and into the heat sink 1, and end, e.g., in a sphere or another expanding or branching structure. It can also taper toward the top. Structures filled with a medium that branch—preferably upward in the heat sink 1, away from the printed circuit board 2—are also conceivable. Other structures are likewise possible, as long as a sufficient or predefined heat dissipation takes place for the relevant component 3 that is to be cooled, and a corresponding heat dissipating medium can be introduced therein. Because they are filled with the medium, these structures should be at least partially hollow, e.g. in the form of a tube, in order to be able to accommodate the medium. The structures illustrated in FIG. 2b are intended to retain the heat dissipating medium in a stationary manner, i.e. there is no circulation of the medium in the interior of the structure, or the thermally conductive element 100.

The embodiment illustrated in FIG. 2c differs from the embodiment illustrated in FIG. 2b in that a structure has been selected here in which the medium circulates independently in the interior. This thermal circulation can be further improved by additional structures in the interior of the thermally conductive element 100, e.g. obstructions. As can be seen in FIG. 2c, the structure can be built such that the medium circulates in two loops, wherein the medium rises in the middle and then falls on both sides of the tube-shaped dome in this embodiment, as described above. Heat can thus be dissipated self-sufficiently in the heat sink 1 through the flow in the interior of the thermally conductive element 100. Further examples of possible structures are tower-like, chimney-like, elongated, hourglass-shaped, or other shapes with rising and/or descending branches in which the medium substantially, preferably entirely, circulates self-sufficiently.

As a rule, through the possibility of printing around structures by means of 3D printing or other printing processes, optimized and varied structures can be provided for cooling, without complicating the production process. Practically any arbitrary complex structure can also be produced with a simultaneous printing of the heat sink 1 onto the thermally conductive element 100 through different printing technologies.

A flow chart for producing the assembly according to the invention is shown in FIG. 3. The heat dissipating assembly has at least one power module, which has a printed circuit board 2 populated with components 3 that are to be cooled, and at least one heat sink 1 that is to be placed on the printed circuit board 2 and above the components 3 that are to be cooled.

Depending on the design of the thermally conductive element 100, there are two different possible production methods.

When one or more of the thermally conductive elements 100 described above is to be used as a separate component, it is placed on at least one of the components 3 in a first step S1. Depending on the embodiment, numerous components 3 can be provided with a thermally conductive element 100, or just one component 3 is provided with a thermally conductive element 100. Not all of the components 3 on the printed circuit board 2 need to be provided with a thermally conductive element 100. Thermally conductive elements 100 produced with another method can likewise be placed on the same printed circuit board 2, but on other components 3, as explained below.

The thermally conductive element 100 can already have a heat dissipating medium in its interior, or the medium is introduced in a further step, e.g. in the second step or a subsequent step. There can be a hole for this, as explained above, which remains open or is sealed. The sealing can be obtained by printing a (thin) layer over the hole. A plate or another means of sealing can also be used, however, to seal the hole and prevent the medium from escaping.

In a second step S2, the heat sink 1 is placed on the components 3 of the printed circuit board 2 and the at least one thermally conductive element 100 located thereon. The heat sink 1 is preferably printed thereon, as explained above, e.g. with a 3D printing process.

Alternatively, one or more of the thermally conductive elements 100 described above, hereinafter referred to as the second thermally conductive element 100, can be produced together with the heat sink in an alternative first step S11, e.g. printed thereon, which unites the first and second steps S1 and S2 in a single step S11.

When both separate thermally conductive elements 100 as well as one or more second thermally conductive elements 100 are to be united in an assembly, the steps S1, S2 and S11 described above are combined. This means that first, the separate thermally conductive elements 100 are applied in the first step S1, and then in the second step S2, the heat sink 1 is placed on top of these thermally conductive elements 100 and at the same time, the heat sink 1 with one or more integrated second thermally conductive elements 100 is placed on top of other components 3. The heat dissipating medium is then placed in the thermally conductive elements 100 that are not yet filled therewith. In doing so, there may be a hole therein that remains open or is closed. The hole can be sealed by means of printing a (thin) layer over the hole. A plate or some other sealing means may also be used to seal the hole and prevent the medium from escaping.

Depending on the embodiment, both means of production can also be combined for the thermally conductive elements 100, as described above. Thus, thermally conductive elements 100 provided as separate components can populate the printed circuit board 2 together with thermally conductive elements 100 produced collectively with the heat sink 1. Depending on the embodiment, the medium can already be placed therein, or it can be added during one of the production steps, or after completion of the assembly, if possible.

As a result of the heat dissipating assembly and the method for production thereof, it is no longer necessary to place an intermediate layer between the heat sink and the components. Consequently, a step is eliminated. Furthermore, varied forms of thermally conductive elements can be used for dissipating the heat in the heat sink, because it is possible to print the heat sink onto the thermally conductive elements. As a result of the separate possible structures for each of the components, a targeted heat dissipation can be provided for each component, without having to add complex additional steps.

### REFERENCE SYMBOLS

1 heat sink
2 printed circuit board
3 components, e.g. components, structures, pathways or via holes
4 heat dissipating layer, gap filler
100 thermally conductive element(s)

1. A heat dissipating assembly, wherein the heat dissipating assembly comprises at least one power module that contains a printed circuit board populated with components that need to be cooled, and at least one heat sink located on the printed circuit board and over the components that are to be cooled, wherein there is at least one thermally conductive element located on at least one of the components that is to be cooled, which has a predefined structure, which extends away from the printed circuit board into the heat sink, and wherein the thermally conductive element contains a heat dissipating medium in its interior.

2. The assembly according to claim 1, wherein the thermally conductive element is in the form of a heatpipe.

3. The assembly according to claim 1, wherein the thermally conductive element has a hollow structure, into which the heat dissipating medium is placed, or it has a hollow structure that is formed such that the heat dissipating medium circulates therein.

4. The assembly according to claim 1, wherein the thermally conductive element is placed as a separate component on the at least one of the components that are to be cooled, or is integrated in the heat sink by means of a printing process.

5. The assembly according to claim 1, wherein the thermally conductive element has at least one hole facing the at least one of the components that are to be cooled, through which the heat dissipating medium can escape and come in contact with the components such that a gap existing between the components and the heat sink is at least partially filled.

6. The assembly according to claim 1, wherein the heat dissipating medium is a liquid, gas, sodium, or other material suitable for dissipating heat.

7. A method for producing a heat dissipating assembly, wherein the heat dissipating assembly comprises at least one power module that contains a printed circuit board populated with components that need to be cooled, and at least one heat sink located on the printed circuit board and over the components that are to be cooled, wherein
at least one thermally conductive element is placed on the printed circuit board on at least one of the components that are to be cooled, which extends away from the printed circuit board, in a first step, and the heat sink is located above of the components on the printed circuit board and the at least one thermally conductive element located thereon, wherein the thermally conductive element has a heat dissipating medium in its interior, or a heat dissipating medium is placed therein in or prior to the first step or in or after the second step, and/or
the heat sink is placed on the components of the printed circuit board in an alternative first step or the second step, wherein at least one second thermally conductive element is integrated in the heat sink during the production of the heat sink, and a heat dissipating element is placed in the second and/or first thermally conductive element in another step.

8. The method according to claim 7, wherein the at least one first or second thermally conductive element has a hole through which the heat dissipating medium is placed in the thermally conductive element wherein the hole opens toward the components, in order to allow the heat dissipating medium to at least partially fill a gap existing between the components and the thermally conductive element.

9. The method according to claim 8, wherein the at least one first or second thermally conductive element has at least one hole through which the heat dissipating medium is placed in the thermally conductive element wherein the hole is sealed after it has been filled with the heat dissipating medium.

10. The method according to claim 7, wherein the predefined structure for each of the thermally conductive elements is formed such that the heat dissipating medium circulates therein.
